(19) United States
(12) Patent Application Publication
(10) Pub. No.: US 2024/0394426 A1
(43) Pub. Date: Nov. 28, 2024

(54) METHOD AND SYSTEM FOR SIMULTANEOUS SEMANTIC MAPPING AND INVESTIGATION OF A BUILT ENVIRONMENT

(71) Applicant: ELBIT SYSTEMS C4I AND CYBER LTD., Netanya (IL)

(72) Inventors: Or TZLIL, Netanya (IL); Tal FEINER, Netanya (IL); Yair KAHN, Netanya (IL); Amit NATIV, Netanya (IL)

(73) Assignee: ELBIT SYSTEMS C4I AND CYBER LTD., Netanya (IL)

(21) Appl. No.: 18/789,930

(22) Filed: Jul. 31, 2024

Related U.S. Application Data
(63) Continuation of application No. PCT/IL2023/050238, filed on Mar. 7, 2023.

(30) Foreign Application Priority Data
Mar. 7, 2022 (IL) 291178

(51) Int. Cl. G06F 30/13

(52) U.S. Cl. CPC G06F 30/13

(57) ABSTRACT

A method and a system for simultaneous semantic mapping and investigation of a built environment are provided herein. The method may include: obtaining distance readings from a moving agent to a built environment; applying the distance readings to a semantic classifier thereby classifying a set of the distance readings into respective semantic built elements selected from a predefined list of two or more types of built elements; repeating the classifying of the distance readings until a connected set of built elements is generated, defining a built volume; detecting at least one opening in the built volume leading to a further built volume; repeating said obtaining, said applying and said classifying, until a connected set of built elements is generated, defining the further built volume; and generating a vectorial map semantically representing the built elements in each of the built volume and the further built volume, and the opening therebetween.

### CROSS REFERENCE TO RELATED APPLICATIONS

This application is a Continuation of International Application No. PCT/IL2023/050238, filed Mar. 7, 2023, which claims priority from Israel Patent Application No. 291178, filed Mar. 7, 2022, both of which are incorporated herewith by reference in their entirety.

### FIELD OF THE INVENTION

The present invention relates generally to the field of mapping and investigating an environment, and more particularly to simultancous semantic mapping and investigation of a built environment.

### BACKGROUND OF THE INVENTION

Mapping and investigating an unknown environment are ongoing challenges in the navigation domain and becomes even more applicable for the use of autonomous agents such as drones and other platforms.

Most autonomous agents relay on their perception to make precise and intelligent decisions. Specifically, in exploration, the agent is expected to understand and explore it's surrounding by moving around and expending the surrounding's map. The generated map represents the agent's memory and understanding of its environment.

Over the past two decades, occupancy-grid-based maps (OGM) have been used for autonomous avigation and exploration. An OGM represents the probability for obstacle to be in each area of two-dimensional grid. Since OGM suffer from oversimplification, alternative method of study called semantic simultaneous localization and mapping (SLAM) has been introduced. Semantic SLAM main idea is to use labeled data in the form of semantic information, to enrich OGM.

Both OGM and semantic SLAM (which rely on OGM) suffer from various disadvantages. For large spaces, OGM requires the tradeoff between computer resources and map resolution and thus suffer from lack of scalability. The localization precision of OGM is bounded by the OGM cell resolution. Sending large OGMs can cause traffic jams in large networks and therefore affects cooperative mapping for multiple autonomous agents.

### SUMMARY OF THE INVENTION

In order to address the aforementioned challenges, some embodiments of the present invention attempt to create a vectorial map of an agent's environment (human or robot) using a semantic classification of objects into one of three (or more) object types selected from a closed list, for example: walls, passages and non-wall or passages objects (residual definition). The mapping and investigation are carried out under the assumption of a built environment (either indoors or outdoors). This assumption allows using a more efficient classifier.

Sensors of different types such as light detection and ranging (LIDAR) or any other type of sensors, provide readings of the distance from the agent to obstacles in their immediate environment. The reading values are entered into a semantic classifier which can determine whether a particular set of readings is appropriate for a wall (surface barrier with boundaries), a passage (an opening in a wall with boundaries and a direction to another room) or any object with known boundaries which is not attached to a wall or passage. Each of these objects may have a unique semantic visual representation such as a plane for a wall, an ellipse for an object and an arrow for a passage.

According to some embodiments of the present invention, the investigation process is carried out by creation the vectorial map locally, at room level (and then room after room), so that a room is considered fully explored only after assembling a connected set of walls and paths defining that room.

According to some embodiments of the present invention, for each room, a passage leading to an unexplored room and a potential research point can be indicated (so that the agent will go on and continue the mapping).

According to some embodiments of the present invention, the entire vector map may be stored in the computer memory as a directed graph where the rooms are marked as vertices and passages as edges and the objects in the room according to the selected graphical representation.

Advantageously, embodiments of the present invention assume a known structure of straight walls and paths (as opposed to free form environment). This reduces computational complexity and allows the use of a simple classifier.

Further advantageously, the investigation is carried out room after room so that once a room is fully investigated (a connected set of walls and passages), the investigation proceeds to other unexamined rooms without taking into account the already investigated rooms. This approach provides scalability.

Embodiments of the present invention can also work outside at street level, where instead of a room there is a street, instead of walls there are building lines and instead of passages there are crossroads. Each street is considered to be fully explored after the assembly of a connected set of building lines and road junctions. Any object other than a building line or road junction is considered an obstacle.

Further advantageously the invention provides standardization of investigating and mapping of structured environments (indoors and outdoors). The invention produces a common language for internal and external urban navigation. The vectorial map is generated in such a way that it is divided into categories and as a data structure it is easy to send online, allowing communication between a large number of agents navigating inside and outside buildings.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a high-level block diagram illustrating a mobile agent capable of simultaneous semantic mapping and investigation of a built environment in accordance with embodiments of the present invention;

FIG. 2 is a high-level flowchart illustrating a method of simultaneous semantic mapping and investigation of a built environment in accordance with some embodiments of the present invention;

FIGS. 3A and 3B are a built environment and a semantic vectorial mapping thereof in accordance with some embodiments of the present invention;

FIGS. 4A and 4B are semantic vectorial maps illustrating aspects in accordance with some embodiments of the present invention;

FIG. 5 shows a partial mapping of a built environment into vectorial semantic indicators in accordance with some embodiments of the present invention;

FIGS. 6A and 6B are semantic indications on built environment illustrating aspects in accordance with some embodiments of the present invention;

FIG. 7 is a semantic vectorial map of a built environment illustrating an aspect in accordance with some embodiments of the present invention; and

FIG. 8 shows an outdoor built environment with semantic mapping thereof in accordance with some embodiments of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following description, various aspects of the present invention will be described. For purposes of explanation, specific configurations and details are set forth in order to provide a thorough understanding of the present invention. However, it will also be apparent to one skilled in the art that the present invention may be practiced without the specific details presented herein. Furthermore, well-known features may be omitted or simplified in order not to obscure the present invention.

Unless specifically stated otherwise, as apparent from the following discussions, it is appreciated that throughout the specification discussions utilizing terms such as “processing”, “computing”, “calculating”, “determining”, or the like, refer to the action and/or processes of a computer or computing system, or similar electronic computing device, that manipulates and/or transforms data represented as physical, such as electronic, quantities within the computing system's registers and/or memories into other data similarly represented as physical quantities within the computing system's memories, registers or other such information storage, transmission or display devices.

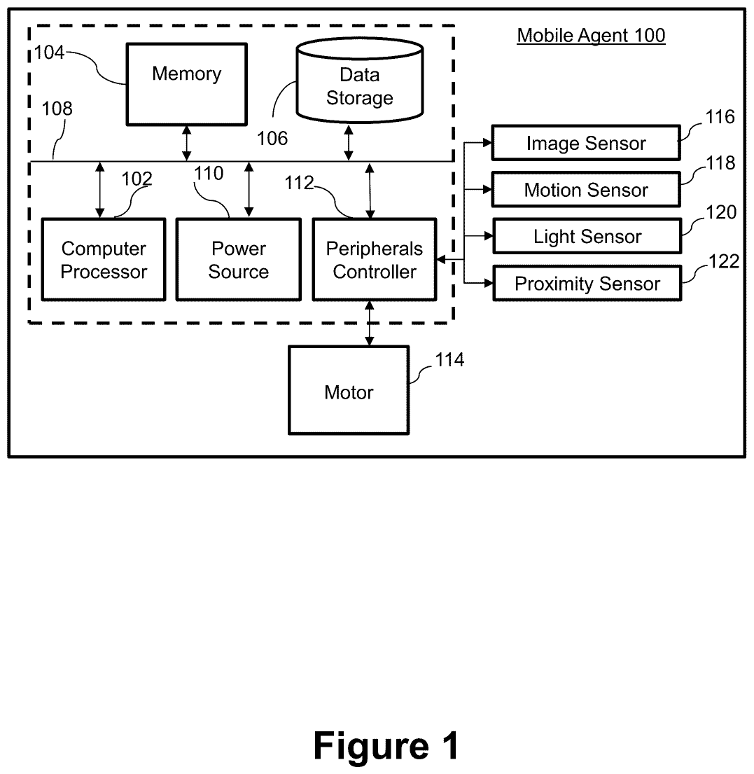

FIG. 1 is a high-level block diagram illustrating a mobile agent capable of simultaneous semantic mapping and investigation of a built environment in accordance with embodiments of the present invention.

Mobile agent 100 may include a memory 104, connected via a bus 108 to a data storage 106 and further connected to a computer processor 102, power source 110 and a peripherals controller 112 which in turn in connected to a plurality of sensors such as image sensor 116, motion sensor 118, light sensor 120, and proximity sensor 122. peripherals controller 112 is also connecter to a motor 114 which in turn is driving a mobility mechanism (not shown) allowing the mobile agent to move freely within an environment and explore and map its surrounding.

In accordance with some embodiments of the present invention, at least one sensors 116-122 may be configured to obtain distance readings from the moving agent to a built environment. Memory 104 and data storage 106 may include a set of instructions that when executed cause computer processor 102 to: apply the distance readings to a semantic classifier, thereby classifying a set of the distance readings into respective semantic built elements selected from a predefined list of two or more types of built elements; repeat the classifying of the distance readings until a connected set of built elements is generated, defining a built volume; detect at least one opening in the built volume leading to a further built volume; repeat the obtaining, the applying and the classifying, until a connected set of built elements is generated, defining the further built volume; and generate a vectorial map semantically representing the built elements in each of the built volume and the further built volume, and the opening therebetween. The map is referred herein as Sparse Semantic Geometrical Map (SSGM).

According to some embodiments of the present invention, the vectorial semantical representation represents the built elements in each of the built volume and the further built volume, and the opening between the built volume and the further built volume. In some embodiments, the vectorial semantical representation is in a form of a directed graph where the built volumes are represented as vertices and wherein the passages between the built volumes are represented as edge.

Advantageously, this form of vectorial representation contributes to both scalability of the mapping and also to the compactness of the map in terms of data storage usage.

According to some embodiments of the present invention, the built volume comprises a room and wherein the built elements comprise at least one of: a wall, a passage, and an object which is neither a wall nor a passage.

According to some embodiments of the present invention, the built volume comprises a street and wherein the built elements comprise at least one of: a building line, a crossroad, and an object which is neither a building line nor a crossroad.

According to some embodiments of the present invention, the built elements are semantically represented as plane for the wall or the building line and a directed arrow for the passage or the crossroad.

According to some embodiments of the present invention, the vectorial map is stored as a directed graph where the built volumes are represented as a vertices and wherein the passages between the built volumes are represented as edges.

According to some embodiments of the present invention, the mobile agent repeats the aforementioned steps for further built volumes until the built environment is investigated in its entirety.

According to some embodiments of the present invention, the distance readings are achieved by receiving reflections of a radiation source from the built environment.

It is understood that while normally the mobile agent is a drone or a robot which can be fully autonomous or semi-autonomous, the mobile agent can also be in the form of a human mounted device configured to be operated by a human exploring and mapping his or her environment.

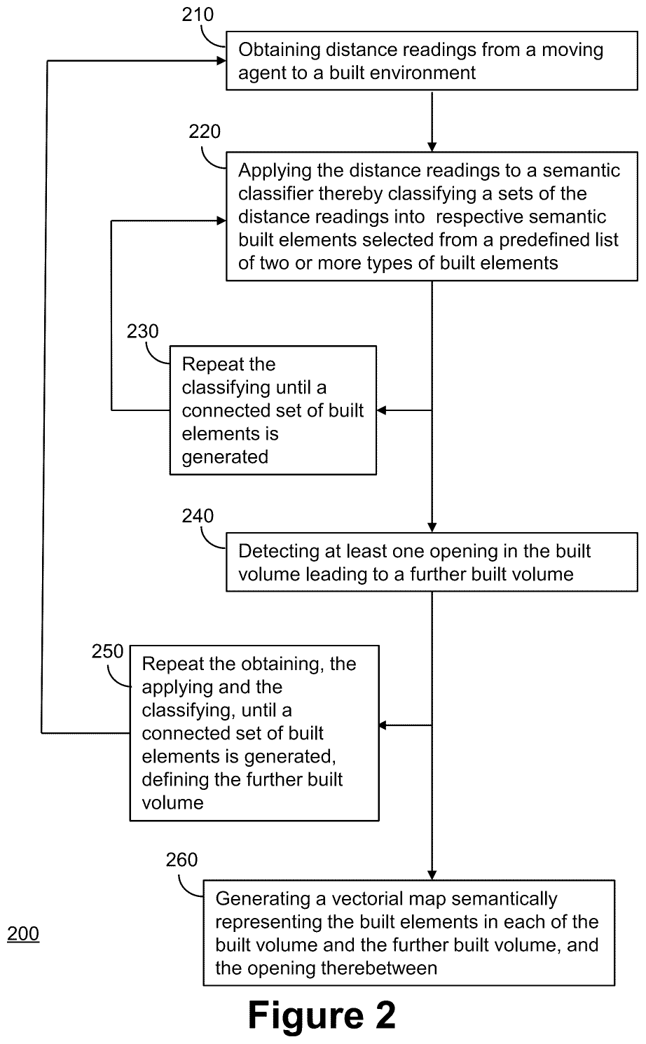

FIG. 2 is a high-level flowchart illustrating a method of simultaneous semantic mapping and investigation of a built environment in accordance with some embodiments of the present invention. Method 200 may include the following steps: obtaining distance readings from a moving agent to a built environment 210; applying the distance readings to a semantic classifier thereby classifying a set of the distance readings into respective semantic built elements selected from a predefined list of two or more types of built elements 220; repeating the classifying of the distance readings until a connected set of built elements is generated, defining a built volume 230; detecting at least one opening in the built volume leading to a further built volume 240; repeating the obtaining, the applying and the classifying, until a connected set of built elements is generated. defining the further built volume 250; and generating a vectorial map semantically representing the built elements in each of the built volume and the further built volume, and the opening therebetween 260.

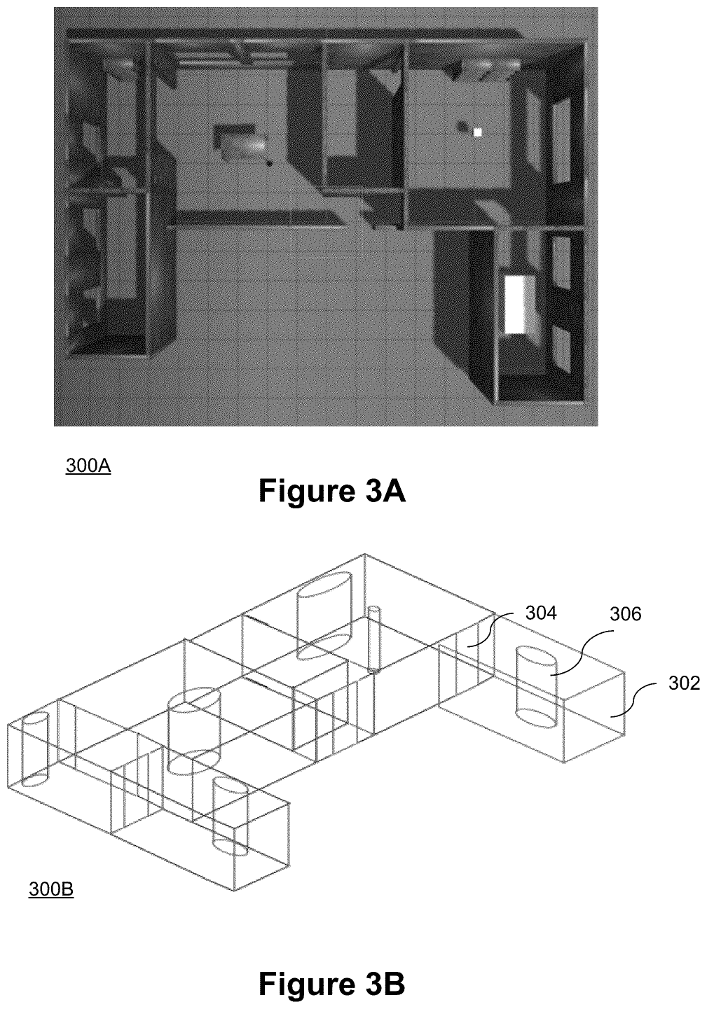

FIGS. 3A and 3B are a built environment and a semantic vectorial mapping thereof in accordance with some embodiments of the present invention. FIG. 3A shows a top view of a built environment 300A. FIG. 3B shows a semantical vectorial map 300B where each of built elements: wall (for example wall 302), passage (for example passage 304), and object (for example object 306) have been mapped during exploration of the built environment. The outcome is a fully descriptive map showing all rooms and the passages between them and additionally any object which is neither a wall nor a passage is also indicated.

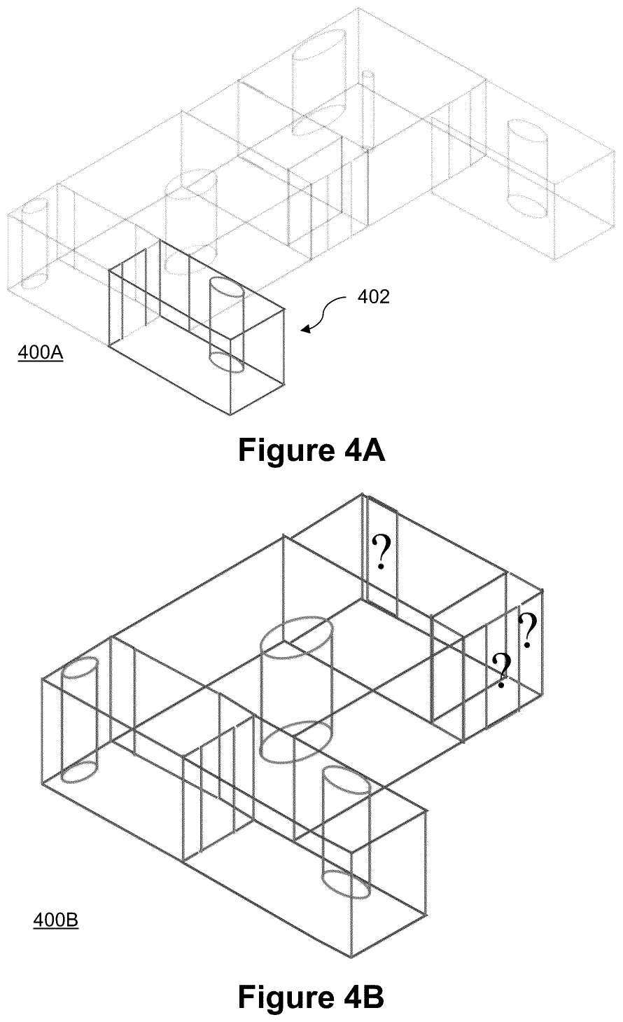

FIGS. 4A and 4B are semantic vectorial maps illustrating aspects in accordance with some embodiments of the present invention. FIG. 4A shows a vectorial semantic map 400A illustrating the scalability of embodiments of the present invention. As soon as a room (for example room 402) is classified by completing the exploration of a connected set of walls and passages, further rooms can be explored without any need to reiterate the fully explored rooms. FIG. 4B is a vectorial semantic map 400B illustrating how embodiments of the present invention allow the indication of unexplored areas indicated herein by question marks—where a full rooms is yet to be mapped and direct the mobile agent to the unexplored areas. The structure of the map can be used as a graph. Each room represents a node, and each exit is edge. Exits that are not yet connected to another room are potential exploration goals.

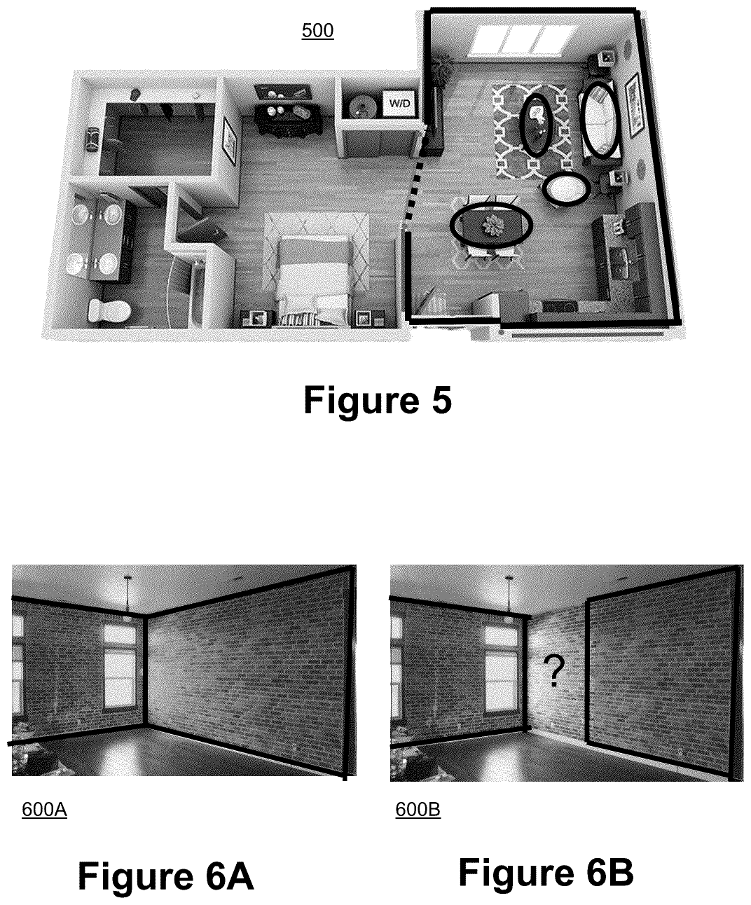

FIG. 5 shows a partial mapping 500 of a built environment into vectorial semantic indicators in accordance with some embodiments of the present invention. Full lines indicate walls, dashed lines indicate passages and ellipses indicate objects.

FIGS. 6A and 6B are semantic indications on built environment images 600A and 600B respectively, illustrating aspects in accordance with some embodiments of the present invention; An unexplored area in 6B is any part of the semantic map that is not defined as part of the room for example the part of the wall indicated by a question mark.

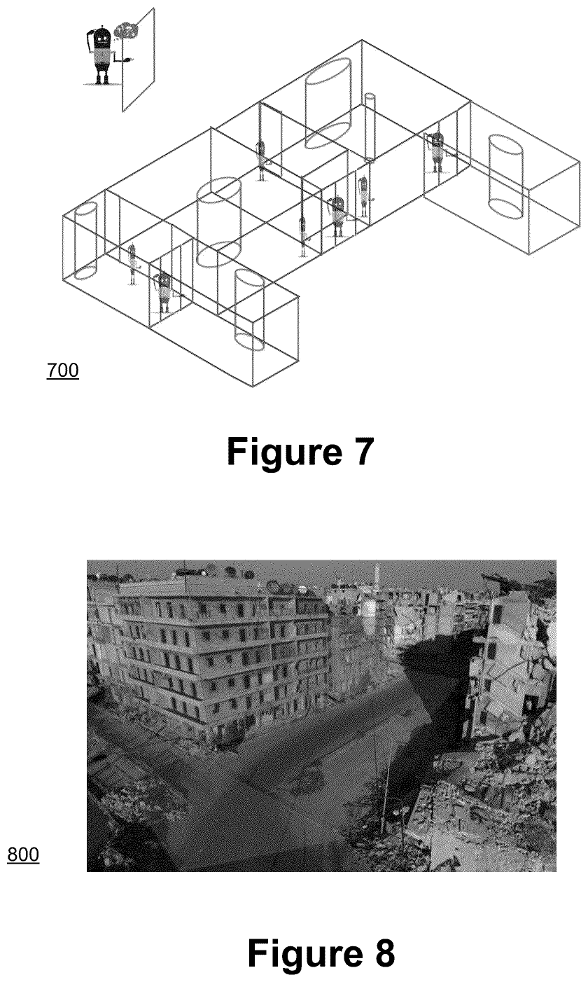

FIG. 7 is a semantic vectorial map 700 of a built environment illustrating an aspect in accordance with some embodiments of the present invention. Localization in a known map sometimes requires a mobile agent to estimate its position without any prior knowledge, this problem, namely the “kidnapped robot problem”, requires searching all over the map for the most probable position of the robot. In OGM this task sometimes leads to inconsistent estimate. However, in the SSGM according to embodiments of the present invention, each object is semantic, and has more inference on the search possibilities. In this scenario, the agent sees a door. It then tracks its hypothesis's that it probably stands in front of a door. Using recursive Bayesian updates to converge to its true position.

FIG. 8 shows an outdoor built environment with semantic mapping thereof in accordance with some embodiments of the present invention. The aforementioned invention can be easily extended to outdoor built environment: outer walls of buildings instead of walls and crossroads instead of passages. This way a full street map of a city can be represented as a vectorial semantic map in accordance with some embodiment of the present invention.

The technique of sparse semantic mapping using simple geometrical shapes can be also used outdoors, in urban areas. This common language, i.e., map can be used for cooperative localization for cross-platform agents, e.g., UAV and UGV. The expended map will also contain objects like buildings as cuboids, roads as bounded planes and external windows.

In the above description the computer processor may include at least one processor configured to execute computer programs, applications, methods, processes, or other software to perform embodiments described in the present disclosure. For example, the processing device may include one or more integrated circuits, microchips, microcontrollers, microprocessors, all or part of a central processing unit (CPU), graphics processing unit (GPU), digital signal processor (DSP), field-programmable gate array (FPGA), or other circuits suitable for executing instructions or performing logic operations. The processing device may include at least one processor configured to perform functions of the disclosed methods. The processing device may include a single-core or multiple core processors executing parallel processes simultaneously. In one example, the processing device may be a single-core processor configured with virtual processing technologies. The processing device may be implemented using a virtual machine architecture or other methods that provide the ability to execute, control, run, manipulate, store, etc., multiple software processes, applications, programs, etc. In another example, the processing device may include a multiple-core processor architecture (e.g., dual, quad-core, etc.) configured to provide parallel processing functionalities to allow a device associated with the processing device to execute multiple processes simultaneously. It is appreciated that other types of processor architectures could be implemented to provide the capabilities disclosed herein.

In some embodiments, the computer processor may use a memory interface to access data and a software product stored on a memory, or a data storage or a non-transitory computer-readable medium or to access a data structure. As used herein, a non-transitory computer-readable storage medium refers to any type of physical memory on which information or data readable by at least one processor can be stored. Examples include random access memory (RAM), read-only memory (ROM), volatile memory, nonvolatile memory, hard drives, CD ROMs, DVDs, flash drives, disks, any other optical data storage medium, a PROM, an EPROM, a FLASH-EPROM or any other flash memory, NVRAM, a cache, a register, any other memory chip or cartridge, and networked versions of the same. The terms “memory” and “computer-readable storage medium” may refer to multiple structures, such as a plurality of memories or computer-readable storage mediums located within the mobile agent, or at a remote location. Additionally, one or more computer-readable storage mediums can be utilized in implementing a computer-implemented method. The term “computer-readable storage medium” should be understood to include tangible items and exclude carrier waves and transient signals.

It is further understood that some embodiments of the present invention may be embodied in the form of a system, a method, or a computer program product. Similarly, some embodiments may be embodied as hardware, software, or a combination of both. Some embodiments may be embodied as a computer program product saved on one or more non-transitory computer-readable medium (or mediums) in the form of computer-readable program code embodied thereon. Such non-transitory computer-readable medium may include instructions that when executed cause a processor to execute method steps in accordance with embodiments. In some embodiments, the instructions stored on the computer-readable medium may be in the form of an installed application and in the form of an installation package.

Such instructions may be, for example, loaded by one or more processors and get executed. For example, the computer-readable medium may be a non-transitory computer-readable storage medium. A non-transitory computer-readable storage medium may be, for example, an electronic, optical, magnetic, electromagnetic, infrared, or semiconductor system, apparatus, or device, or any combination thereof.

Computer program code may be written in any suitable programming language. The program code may execute on a single computer system, or on a plurality of computer systems.

One skilled in the art will realize the invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes that come within the meaning and range of equivalency of the claims are therefore intended to be embraced therein.

In the foregoing detailed description, numerous specific details are set forth in order to provide an understanding of the invention. However, it will be understood by those skilled in the art that the invention can be practiced without these specific details. In other instances, well-known methods, procedures, and components, modules, units, and/or circuits have not been described in detail so as not to obscure the invention. Some features or elements described with respect to one embodiment can be combined with features or elements described with respect to other embodiments.

1. A method of simultaneous semantic mapping and investigation of a built environment, the method comprising:
obtaining distance readings from a moving agent to a built environment;
applying the distance readings to a semantic classifier to classify a set of the distance readings into respective semantic built elements selected from a closed list of two or more predefined types of built elements;
repeating the classifying of the distance readings until a connected set of built elements is generated, defining a built volume;
detecting at least one opening in the built volume leading to a further built volume;
repeating said obtaining, said applying and said classifying, until a connected set of built elements is generated, defining the further built volume; and
generating a vectorial semantical representation of the built elements in each of the built volume and the further built volume, and the opening between the built volume and the further built volume,
wherein the vectorial semantical representation is in a form of a directed graph where the built volumes are represented as vertices and wherein the passages between the built volumes are represented as edge.

2. The method according to claim 1, wherein the built volume comprises a room and wherein the built elements comprise at least one of: a wall, a passage, and an object which is neither a wall nor a passage.

3. The method according to claim 1, wherein the built volume comprises a street and wherein the built elements comprise at least one of: a building line, a crossroad, and an object which is neither a building line nor a crossroad.

4. The method according to claim 1, wherein the built elements are semantically represented as plane for the wall or the building line and a directed arrow for the passage or the crossroad.

5. The method according to claim 1, further comprising repeating the method, for further built volumes until the built environment is investigated in its entirety.

6. The method according to claim 1, wherein the distance readings are achieved by receiving reflections of a radiation source from the built environment.

7. The method according to claim 1, wherein the moving agent is a drone or a robot.

8. A mobile agent capable of simultaneous semantic mapping and investigation of a built environment, the mobile agent comprising:
at least one sensor configured to obtain distance readings from the moving agent to a built environment;
a computer processor; and
computer memory comprising a set of instructions that when executed cause the computer processor to:
apply the distance readings to a semantic classifier, to classify a set of the distance readings into respective semantic built elements selected from a closed list of two or more predefined types of built elements;
repeat the classifying of the distance readings until a connected set of built elements is generated, defining a built volume;
detect at least one opening in the built volume leading to a further built volume;
repeat said obtaining, said applying and said classifying, until a connected set of built elements is generated, defining the further built volume; and
generate a vectorial semantical representation of the built elements in each of the built volume and the further built volume, and the opening between the built volume and the further built volume,
wherein the vectorial semantical representation is in a form of a directed graph where the built volumes are represented as vertices and wherein the passages between the built volumes are represented as edge.

9. The mobile agent according to claim 8, wherein the built volume comprises a room and wherein the built elements comprise at least one of: a wall, a passage, and an object which is neither a wall nor a passage.

10. The mobile agent according to claim 8, wherein the built volume comprises a street and wherein the built elements comprise at least one of: a building line, a crossroad, and an object which is neither a building line nor a crossroad.

11. The mobile agent according to claim 9, wherein the built elements are semantically represented as plane for the wall or the building line and a directed arrow for the passage or the crossroad.

12. The mobile agent according to claim 8, wherein the computer processor is further configured to repeat the obtaining, the classifying, and the detecting. for further built volumes until the built environment is investigated in its entirety.

13. The mobile agent according to claim 8, wherein the distance readings are achieved by receiving reflections of a radiation source from the built environment.

14. The mobile agent according to claim 8, wherein the moving agent is a drone or a robot.

15. A non-transitory computer-readable medium for simultaneous semantic mapping and investigation of a built environment, by a mobile agent, the computer-readable medium comprising a set of instructions that when executed cause at least one computer processor to:
obtain distance readings from the moving agent to a built environment:
apply the distance readings to a semantic classifier, to classify a set of the distance readings into respective semantic built elements selected from a closed list of two or more predefined types of built elements;
repeat the classifying of the distance readings until a connected set of built elements is generated, defining a built volume;
detect at least one opening in the built volume leading to a further built volume;
repeat said obtaining, said applying and said classifying, until a connected set of built elements is generated, defining the further built volume; and
generate a vectorial semantical representation of the built elements in each of the built volume and the further built volume, and the opening between the built volume and the further built volume,
wherein the vectorial semantical representation is in a form of a directed graph where the built volumes are represented as vertices and wherein the passages between the built volumes are represented as edge.

16. The non-transitory computer-readable medium according to claim 15, wherein the built volume comprises a room and wherein the built elements comprise at least one of: a wall, a passage, and an object which is neither a wall nor a passage.

17. The non-transitory computer-readable medium according to claim 15, wherein the built volume comprises a street and wherein the built elements comprise at least one of: a building line, a crossroad, and an object which is neither a building line nor a crossroad.

18. The non-transitory computer-readable medium according to claim 17, wherein the built elements are semantically represented as plane for the wall or the building line and a directed arrow for the passage or the crossroad.
